(19) United States
(12) Patent Application Publication
(10) Pub. No.: US 2026/0289061 A1
(43) Pub. Date: Sep. 24, 2026

(54) EULERPATH-BASED TRANSISTOR PLACEMENT

(71) Applicant: GDM Holding LLC, Mountain View, CA (US)

(72) Inventors: Dino Ruic, Santa Clara, CA (US); Xiaoqing Xu, London (GB)

(21) Appl. No.: 19/084,958

(22) Filed: Mar. 20, 2025

(51) Int. Cl. G06F 30/392; G06F 30/323

(52) U.S. Cl. CPC G06F 30/392; G06F 30/323

(57) ABSTRACT

The technology is related to Eulerpath-based transistor placement in integrated circuit (IC) design. The technology transforms a transistor netlist into a graph representation, and identifies contiguous Eulerpaths in the graph representation. Each node in the graph represents either a transistor or net in the netlist. The Eulerpaths may be scored based on criteria such as source/drain alignment, gate alignment, routing congestion, and/or the like. Lower-scoring Eulerpaths may be pruned and/or ignored. The remaining Eulerpaths may then be aligned, and the aligned Eulerpaths may be placed on a chip canvas. Thus, the technology provides more compact IC layouts in terms of chip area than existing techniques, minimizes diffusion breaks, optimizes interconnect length, and may enhance thermal distribution and power delivery.

### BACKGROUND

Electronic design automation (EDA), also referred to as electronic computer-aided design (ECAD), refers to a process, and set of software tools, used for designing electronic systems, such as integrated circuits (ICs), printed circuit boards (PCBs), and the like. The EDA process encompasses a series of steps to design and implement digital circuits from high-level specifications to physical hardware. Some steps in the EDA process include logic synthesis and physical design. Physical design is based on the gate-level netlist, which is the result of the logic synthesis. During the physical design stage, the gate-level netlist is converted into a physical layout that can be manufactured as an IC.

Typical EDA flows include a transistor placement process, which may occur during the placement phase of a physical design flow or during a custom layout design process, such as when creating standard cells or custom designed cells. Transistor placement determines the physical arrangement of transistors within a cell, usually with a goal of optimizing area, performance, and power while ensuring adherence to design rules. Some transistor placement processes include utilizing optimization techniques to achieve the best possible balance between critical design while ensuring adherence to design rules. By automating the optimization of the transistor placement process, optimization techniques can potentially reduce design time, improve overall chip quality, and help meet increasingly stringent design constraints in modern semiconductor technologies.

Conventional optimization methods for transistor placement typically employ techniques like simulated annealing (SA), force-directed placement, and genetic algorithms (GA). These approaches often start with an initial random or semi-intelligent placement and iteratively improve that placement based on a cost function. Such a cost function may consider wirelength, timing, congestion, and/or other metrics. Another conventional optimization approach includes combinatorial methods. In the context of transistor placement, a combinatorial method is an optimization approach that formulates a placement problem as a combinatorial problem, where the goal is to find the best arrangement of transistors by exploring and evaluating different combinations of possible placements.

However, conventional optimization techniques may suffer from drawbacks or limitations. One drawback for some optimization techniques, is that they are computationally expensive in terms of time and resource consumption, especially for large designs, thereby limiting the number of iterations that can be practically performed. For example, in relatively large designs with hundreds to millions of transistors, combinatorial methods become infeasible due to their exponential scaling.

Another common drawback of such techniques is that they can become stuck in local optima traps, wherein the solution being optimized gets stuck in a suboptimal configuration (the local optimum) instead of reaching the best possible solution (the global optimum). Additionally, many conventional optimization methods struggle to effectively balance multiple competing objectives simultaneously, such as area, power, and performance. Furthermore, some conventional optimization methods may not account for modern manufacturing constraints, and therefore, such optimization methods may produce layouts that are technically correct but difficult to manufacture. Thus, such approaches can result in insufficient and/or ineffective solutions.

### SUMMARY

The present technology is related to transistor placement methodologies during the physical design stage of an EDA flow. Aspects of the technology introduce new ways to perform transistor placement using Eulerpaths, which place a relatively large number of transistors that maximizes diffusion sharing between transistors.

Some embodiments include a computer-implemented method of Eulerpath transistor placement. The method includes converting, by at least one processor, a netlist into a graph data structure, wherein each node in the graph data structure represents either a transistor in the netlist or a net in the netlist. The method includes identifying, by the at least one processor, a set of Eulerpaths in the graph data structure. The method includes aligning, by the at least one processor, a subset of the identified set of Eulerpaths. The method includes placing, by the at least one processor, the aligned Eulerpaths on a chip canvas.

In some embodiments, edges in the graph data structure represent ohmic connections between transistors or nets. In some embodiments, each node representing a net includes a net identifier and each node representing a transistor includes a gate net identifier and orientation information.

In some embodiments, identifying the set of Eulerpaths comprises performing, by the at least one processor, a graph search on the graph data structure. In some embodiments, performing the graph search comprises navigating, by the at least one processor, the graph data structure starting from an initial net node, and iteratively traversing a transistor node and another net node until the initial net node is reached. In some embodiments, identifying the set of Eulerpaths comprises identifying, by the at least one processor, a set of p-channel metal-oxide-semiconductor (PMOS) Eulerpaths by performing the graph search on subgraphs comprising PMOS transistors; and identifying, by the at least one processor, a set of n-channel metal-oxide-semiconductor (NMOS) Eulerpaths by performing the graph search on subgraphs comprising NMOS transistors.

In some embodiments, aligning the subset of the identified set of Eulerpaths comprises identifying, by the at least one processor, gate-aligned Eulerpaths among the identified set of Eulerpaths. In some embodiments, aligning the subset of the identified set of Eulerpaths comprises identifying, by the at least one processor, source/drain-aligned Eulerpaths among the identified set of Eulerpaths.

In some embodiments, aligning the subset of the identified set of Eulerpaths comprises determining, by the at least one processor, a score for each identified Eulerpath based on at least one of an amount of diffusion sharing, a number of gate-alignments, a number of source/drain-alignments, or a number of parallel tracks. In some embodiments, the method further includes: maintaining, by the at least one processor, a subset of Eulerpaths in the set of Eulerpaths having higher scores than other Eulerpaths in the set of Eulerpaths.

In some embodiments, placing the aligned Eulerpaths on the chip canvas comprises placing, by the at least one processor, a Eulerpath or a reversed Eulerpath from the set of Eulerpaths at a current position on the chip canvas. In some embodiments, placing the aligned Eulerpaths on the chip canvas further comprises advancing, by the at least one processor, the current position by a length of the placed Eulerpath. In some embodiments, placing the aligned Eulerpaths on the chip canvas further comprises advancing, by the at least one processor, the current position to a next row in the chip canvas when the current position extends beyond a final column of the chip canvas. In some embodiments, placing the aligned Eulerpaths on the chip canvas further comprises placing, by the at least one processor, a next Eulerpath or a next reversed Eulerpath from the set of Eulerpaths at the current position. In some embodiments, placing the aligned Eulerpaths on the chip canvas further comprises when all of the Eulerpaths in the set of Eulerpaths have been placed, evaluating, by the at least one processor, a wire length of the placed Eulerpaths. In some embodiments, placing the aligned Eulerpaths on the chip canvas further comprises annealing, by the at least one processor, the placement of the Eulerpaths when the evaluated wire length is better than a criterion.

Some embodiments include a computer-readable storage media. The computer-readable storage media is configured to store instructions, which when executed by at least one processor is to cause the at least one processor to perform resynthesis according to any of the methods described previously and/or as discussed herein.

Some embodiments include a computing system. The computing system comprises at least one memory device and at least one processor connected to the at least one memory device. The at least one memory device is configured to store instructions for performing Eulerpath transistor placement during electronic design automation. The at least one processor is configured to execute the instructions to: convert a netlist into a graph data structure, wherein each node in the graph data structure represents either a transistor in the netlist or a net in the netlist; identify a set of Eulerpaths in the graph data structure; align a subset of the identified set of Eulerpaths; and place the aligned Eulerpaths on a chip canvas.

In some embodiments, edges in the graph data structure represent ohmic connections between transistors or nets. In some embodiments, each node representing a net includes a net identifier and each node representing a transistor includes a gate net identifier and orientation information.

In some embodiments, the identification of the set of Eulerpaths comprises perform a graph search on the graph data structure. In some embodiments, performing the graph search comprises navigate the graph data structure starting from an initial net node, and iteratively traversing a transistor node and another net node until the initial net node is reached. In some embodiments, the identification of the set of Eulerpaths further comprises identify a set of p-channel metal-oxide-semiconductor (PMOS) Eulerpaths by performing the graph search on subgraphs comprising PMOS transistors. In some embodiments, the identification of the set of Eulerpaths further comprises identify a set of n-channel metal-oxide-semiconductor (NMOS) Eulerpaths by performing the graph search on subgraphs comprising NMOS transistors.

In some embodiments, the alignment of the subset of the identified set of Eulerpaths comprises identify gate-aligned Eulerpaths among the identified set of Eulerpaths. In some embodiments, the alignment of the subset of the identified set of Eulerpaths comprises identify source/drain-aligned Eulerpaths among the identified set of Eulerpaths.

In some embodiments, the alignment of the subset of the identified set of Eulerpaths comprises determine a score for each identified Eulerpath based on at least one of an amount of diffusion sharing, a number of gate-alignments, a number of source/drain-alignments, or a number of parallel tracks. In some embodiments, the at least one processor is configured to execute the instructions to: maintain a subset of Eulerpaths in the set of Eulerpaths having higher scores than other Eulerpaths in the set of Eulerpaths.

In some embodiments, placing the aligned Eulerpaths on the chip canvas comprises place a Eulerpath or a reversed Eulerpath from the set of Eulerpaths at a current position on the chip canvas.

In some embodiments, placing the aligned Eulerpaths on the chip canvas further comprises advance the current position by a length of the placed Eulerpath. In some embodiments, placing the aligned Eulerpaths on the chip canvas further comprises advance the current position to a next row in the chip canvas when the current position extends beyond a final column of the chip canvas. In some embodiments, placing the aligned Eulerpaths on the chip canvas further comprises place a next Eulerpath or a next reversed Eulerpath from the set of Eulerpaths at the current position. In some embodiments, placing the aligned Eulerpaths on the chip canvas further comprises, when all of the Eulerpaths in the set of Eulerpaths have been placed, evaluate a wire length of the placed Eulerpaths. In some embodiments, placing the aligned Eulerpaths on the chip canvas further comprises anneal the placement of the Eulerpaths when the evaluated wire length is better than a criterion.

### BRIEF DESCRIPTION OF THE DRAWINGS

FIG. 1 illustrates an example electronic design automation flow for use with aspects of the present technology.

FIG. 2A illustrates an example full-adder netlist in accordance with aspects of the present technology.

FIG. 2B illustrates an example a spatial representation of transistor nets corresponding to the full-adder netlist of FIG. 2A.

FIG. 2C illustrates an example physical design or layout corresponding to the full-adder netlist and spatial representation of FIGS. 2A and 2B.

FIG. 3 illustrates an example circuit and corresponding graph data structure in accordance with aspects of the present technology.

FIG. 4 illustrates an example annealing placement process in accordance with aspects of the present technology.

FIG. 5 illustrates an example netlist with possible Eulerpaths through a power supply in accordance with aspects of the present technology.

FIG. 6 illustrates an example standard cell and an Eulerpath placed cell in accordance with aspects of the present technology.

FIG. 7 illustrates an example Eulerpath placement process in accordance with aspects of the present technology.

FIGS. 8A-8B illustrate an exemplary system in which aspects of the technology can be practiced.

### DETAILED DESCRIPTION

The present technology is related to placement of a relatively large numbers of transistors when preparing an IC design, e.g., hundreds or thousands of transistors (or more), which may take place during the physical design phase of EDA. Aspects of the present technology include transistor placement using Eulerpaths. This may include placing a relatively large number of transistors that maximizes diffusion sharing between various transistors. Transistor placement may be made more compact based on whether the source, drain, and/or gate terminals of those transistors is/are assigned to the same net. Such transistors can be placed more compactly by diffusion sharing. Additionally, gates can be aligned such that they can be connected by a vertical polysilicon (poly) line.

One aspect of the present technology includes identifying, or attempting to identify, coverage of a graph, such as a netlist, using Eulerpaths. Suitable Eulerpaths can be discovered in relatively large designs that can then be “peeled off” the graph to decrease the problem size with much better asymptotic scaling in comparison to those of conventional techniques.

The Eulerpaths can be scored based on transistor gate alignments, source/drain alignments, and/or using congestion scores, such as the number of used tracks. Paths that have relatively low scores relative to other paths can be pruned and ignored. Some aspects include developing scoring systems for a target process design kit (PDK) or technology.

Some aspects of the present technology include techniques to reduce the search space for Eulerpaths. In one example, the search space only includes aligned PMOS and NMOS gates, when the netlist is very big. Here, a netlist that is “very big” may refer to a netlist that includes thousands to millions of transistors. In this example, if transistors are preplaced on a chip canvas using a half-perimeter wire length optimization technique (e.g., electrostatic placement, SA, etc.), the expected distance between transistors can be determined, and the Eulerpaths that run through distant transistors can be ignored or pruned.

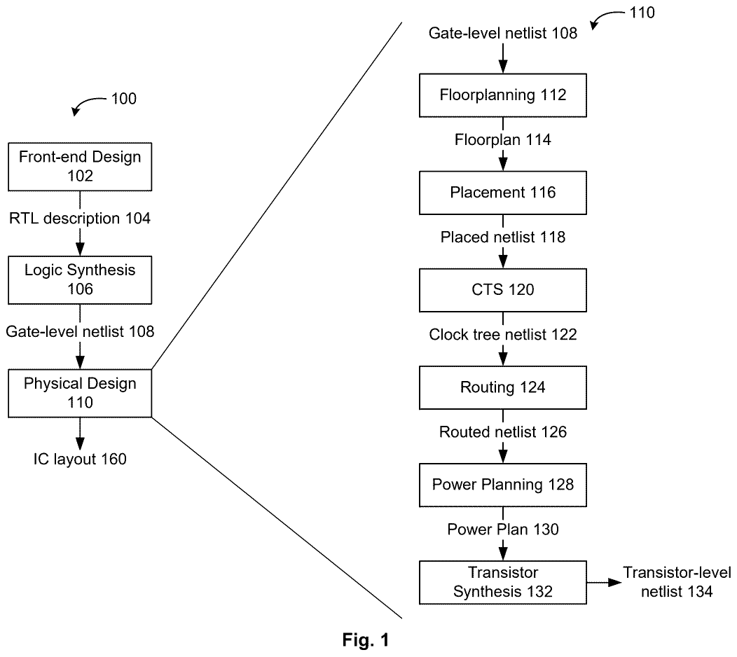

After a netlist coverage of Eulerpaths has been found, the Eulerpaths (or the transistors) can be placed in a same or similar manner as traditional standard cells using, for example, SA and/or the like. These and other aspects of the present technology are described in relation to FIGS. 1-6.

### 1. Electronic Design Automation Examples

EDA is a process, and set of software tools, used for designing electronic systems, such as ICs, PCBs, and the like. The EDA process encompasses a series of steps to design and implement digital circuits from high-level specifications to physical hardware. The process mainly includes steps, such as system design or specification, logic design, logic synthesis, physical design, physical synthesis, physical verification, and tapeout. Additional or alternative steps/processes may be included in an EDA process in other implementations.

FIG. 1 depicts an example EDA flow 100 in accordance with aspects of the present technology. In this example, the EDA flow 100 includes a front-end design flow 102, logic synthesis flow 106, and physical design flow 110. Various commercially available or proprietary EDA tools may be used to perform design and simulation tasks of the EDA flow 100, such as register-transfer level (RTL) synthesis tools, system design and functional verification tools, logic synthesis tools such as graphing engines and optimization engines, physical design tools, circuit design and simulation tools, PCB design tools, and/or the like.

The front-end design flow 102 is the initial phase of the digital design process, which involves creating the functional specification and logical implementation of a circuit. The front-end design flow 102 typically begins with architectural design, where the overall structure and major components of the system are defined based on the project requirements and constraints. Next, an abstract specification of circuit behavior is coded, created, or generated, which specifies the circuit's behavior in terms of data flow between registers and the logical operations performed on that data. In this example, the abstract specification are in the form of an RTL circuit description 104. The RTL description 104 may be expressed using a hardware description language (HDL), such as VHDL, Verilog, MyHDL, Clash, Chisel, and the like. The RTL description 104 defines the flow of data between registers and the logical operations performed on that data. Additionally or alternatively, the RTL description 104 may describe bitstreams for programmable logic devices (PLDs), such as programmable array logic (PAL), complex PLDs, field-programmable gate arrays (FPGAs), programmable System-on-Chip (SoC) platforms, and the like. The RTL description 104 may be generated using a high-level synthesis (HLS) tool. HLS tools automatically synthesize circuits specified using high-level programming languages, such as C, C++, SystemC, MATLAB, and the like, into a functionally-equivalent RTL hardware implementation, such as RTL description 104. In some implementations, functional verification follows the abstract specification coding, such as RTL coding, which involves simulation and testing to ensure the abstract specification, such as the RTL code 104, accurately implements the intended functionality and meets desired design specifications.

Logic synthesis 106 is a process of converting an abstract specification of circuit behavior, such as the RTL description 104, into a circuit design implementation in terms of logic gates, flip-flops, and the like that can be physically implemented on an IC. The logic synthesis flow 106 transforms, translates, or transcodes the RTL description 104 into gate-level descriptions, such as logic gate-level netlist 108. The gate-level netlist 108 is a description of the connectivity of a logic circuit, which is usually in the form of a logical data structure, such as an AND-inverter graph (AIG), binary decision diagram (BDD), sum-of-product form (ΣoΠ), Boolean network, and/or other logical data structure(s). The output of the logic synthesis flow 106, such as the logic gate-level netlist 108, may be the input to a physical processing stage 120 of an EDA process. The logic synthesis flow 106 typically includes three stages: a logic translation stage performed by a translation engine, a logic optimization stage performed by an optimization engine, and a technology mapping stage performed by a technology mapping engine.

The logic translation stage involves a translation engine translating the RTL description 104 into a non-optimized logical netlist based on, for example, technology libraries of standard cells, gates, and/or other logical components. At the logic optimization stage, an optimization engine optimizes the netlist based on design constraints and objectives. The design constraints and objectives may be defined by the libraries, scripts, markup documents, and/or other suitable data structure(s). For example, the synthesis constraints can include environment constraints, design constraints, and logic optimization constraints. The environment constraints include aspects of the external environment where the circuit is intended to operate, such as temperature, voltage, drive, load, and/or the like. The design constraints include design-related aspects of the circuit such as, for example, maximum transition time, maximum fan-out, minimum capacitance, maximum capacitance, and/or the like.

The logic optimization constraints include constraints related to aspects of the optimization of the netlist, such as timing constraints and area constraints. The timing constraints may limit, for example, clock networks, timing paths, critical path delays, asynchronous logic timing, and the like. The area constraints may limit, for example, the maximum number of logic units and the like. To optimize the netlist, the optimization engine may be configured to operate an optimization algorithm. For example, the optimization algorithm may be an SA algorithm flow for And-Inverter Graph (AIG) optimization in which a randomly selected sequence of transformations are applied to a given (current) AIG, and the new AIG depth and node count are used to evaluate the cost or reward for the transformed AIG. However, it should be noted that another optimization algorithm/flow could be used, such as an evolutionary algorithm, GA, Bayesian optimization algorithm, a machine learning approach, and/or other approach.

At the technology mapping stage, the technology mapping engine selects logical elements, such as logic gates, to implement the optimized netlist. This may include, for example, selecting logic unit instances, such as logic gates, from the same or different technology libraries to implement a gate-level logic netlist 108. The selection may be based on various constraints, such as time sequence or other timing constraints, power, performance, and area (PPA) constraints (e.g., power consumption, performance in terms of speed and/or delay, and circuit area), logic unit characteristics, logical relationships, and the area of logic units provided by the technology libraries.

Each logic gate may be a device, or collection of hardware elements, that performs a Boolean function or a logical operation performed on one or more binary inputs that produces a binary output. Examples of such logic gates can include NOT or inverter (INV) gates, AND gates, OR gates, NOT AND (NAND) gates, NOT OR (NOR) gates, exclusive OR (XOR) gates, exclusive NOR (XNOR) gates, compound logic gates such as AND-OR-Inverters (AOI) and OR-AND-Inverters (OAI), Full Adders (FAs), and/or other gates, some or all of which may be formed from combinations of various diodes, transistors, and/or other electrical elements. Various combinations of logic gates may form logic circuits, such as multiplexers, demultiplexers, registers, arithmetic logic units (ALUs), encoders, decoders, computer memory, microprocessors, and/or the like.

The physical design flow 110 transforms the logical representation of a circuit, such as the gate-level netlist 108 from the logic synthesis flow 106, into a physical layout that can be manufactured as an IC, such as IC layout 160. As shown by FIG. 1, the physical design flow 110 in this example includes the following steps or stages: floorplanning 112, placement 116, clock tree synthesis (CTS) 120, routing 124, power planning 128, and transistor synthesis 132 (also known as transistor-level implementation or cell synthesis). The physical design flow 110 may be an iterative process where one or more of the stages/steps may be revisited multiple times as the circuit's design evolves or becomes more optimized. Additionally or alternatively, at least some of the stages/steps in the physical design flow 110 may be run or executed multiple times before moving to a subsequent stage to optimize or refine the desired output of those stages. Additionally or alternatively, at least some of the stages/steps of the physical design flow 110 may be executed concurrently or run simultaneously, such as to optimize placement, routing, and transistor sizing at stages 116, 124, and 132, respectively. Additionally or alternatively, the timing and/or order of individual stages may vary depending on the specific EDA flow 100 and EDA tools being used. For example, in some implementations, aspects of transistor synthesis 132 or one or more other stages may be integrated earlier in the EDA process 100. Furthermore, the physical design flow 110 may include steps/stages in addition or alternative to those shown by FIG. 1. For example, the physical design flow 110 may include thermal analysis, physical verification, and/or tape-out steps/stages.

In the example of FIG. 1, the physical design 110 may begin with the gate-level netlist 108 being input to the floorplanning stage 112. In addition to the gate-level netlist 108, additional inputs to the physical design flow 110, such as at the floorplanning 112, may include, for example, a technology library, timing library, physical library, design constraints, and/or the like. The technology library, provided by the foundry, such as foundry 812, containing information about the available standard cells, geometry of each cell, macros, via information, design rules, manufacturing process(es), and/or the like. This includes both the physical layout details indicated by, for example, a library exchange format (LEF) file, and the electrical/timing characteristics indicated by, for example, a liberty timing file (LIB). The timing library, which may be the LIB part of the technology library, specifies the timing characteristics of standard cells and macros, such as the aforementioned electrical/timing characteristics. The physical library, which may also be part of the LEF part of the technology library, describes the physical layout and geometry of standard cells and macros. The geometric information may be used for initial placement and routing estimations. Additionally or alternatively, the LEF file may contain rules related to the fabrication process, placement and routing design rules, and process information for various layers. The design constraints include clock definitions, timing requirements, and other design rules. Design constraints may be included in a standard design constraints (SDC) file, sometimes referred to as a Synopsys design constraints (SDC) file. In some implementations, a power file, such as a unified power format (UPF) file, which specifies the power intent of the design, including power domains, power switches, and other power management strategies.

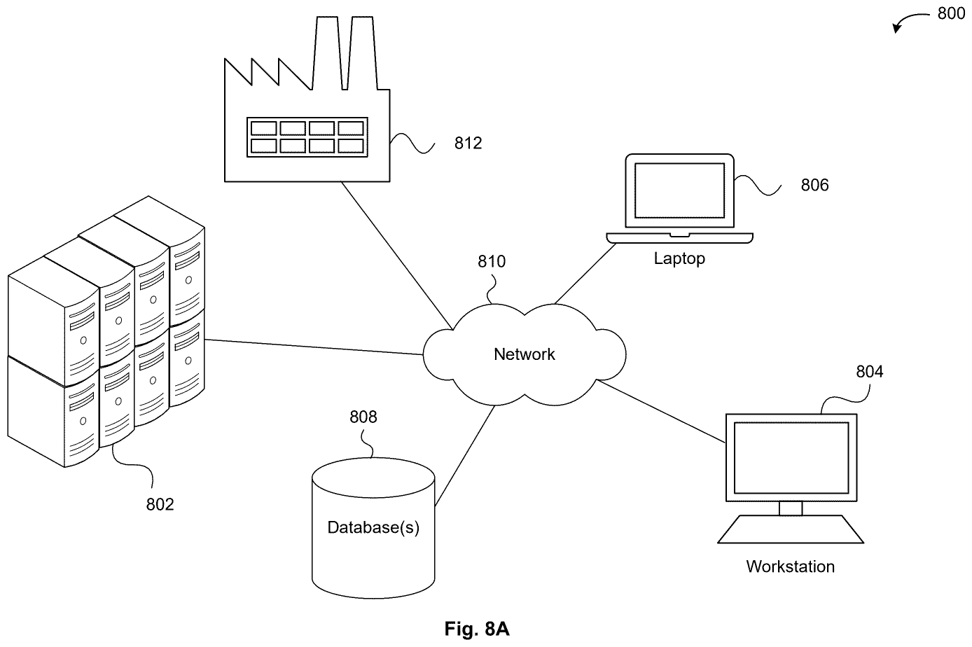

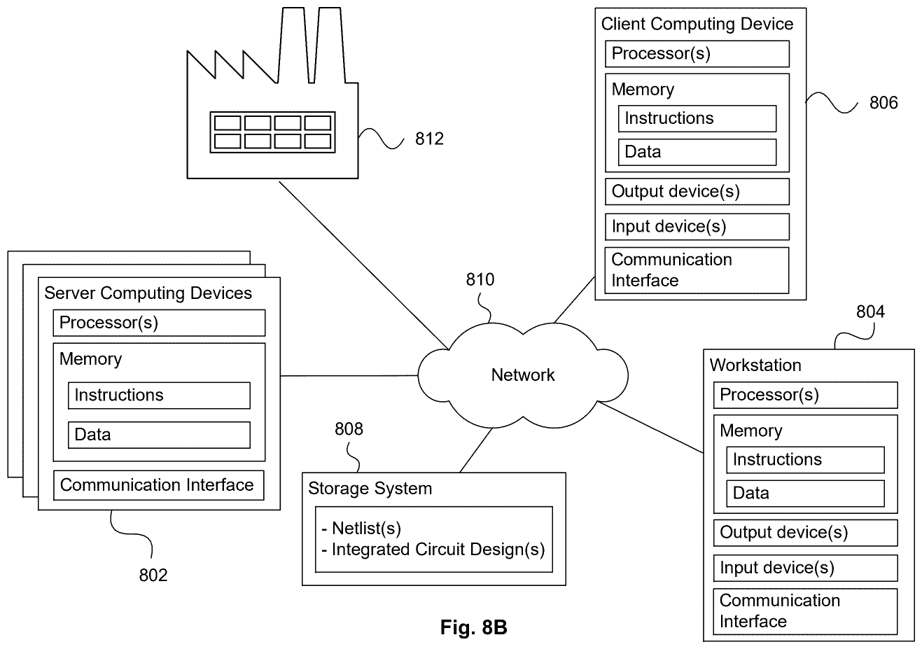

The cells, such as those in a standard cell library, may be relatively small, standardized functional elements of digital logic circuits such as, for example, logic gates (e.g., AND, OR, NOT, NAND, NOR, XOR, FA, etc.), flip-flops, latches, small analog components (e.g., transistors, resistors, capacitors), and/or the like. Standard cells, or standard cell libraries, are typically provided by a foundry or technology library vendor, such as foundry 812 of FIGS. 8A-8B. The macro blocks (or macros) may be relatively large, complex functional blocks that are pre-designed and pre-characterized such as, for example, memory blocks (e.g., SRAM, DRAM, etc.), analog/mixed-signal blocks (e.g., analog-to-digital converters (ADCs), digital-to-analog converters (DACs), phased-locked loops (PLLs), etc.), processor cores, I/O interfaces, and/or the like. Macros are sometimes designed by specialized developer/designer teams, obtained from third-party intellectual property (IP) providers, and/or provided by a foundry or technology library vendor, such as foundry 812 of FIGS. 8A-8B.

Floorplanning 112 is the initial step in physical design flow 110 where the IC's overall structure is determined. Floorplanning 112 typically involves partitioning the chip area into a set of functional blocks, or individual modules, such as a memory subsystem, compute unit, and/or control block(s). Floorplanning 112 may involve allocating space for each block or module in consideration of factors, such as chip size and/or shape, aspect ratio, locations of input/output (I/O) pads (e.g., power, ground, and signal pads), core utilization, and/or other factors. For example, the floorplanning 112 may involve placing input, output, cells, and/or macros onto chip canvases, such that performance metrics (e.g., power consumption, timing, area, wirelength, etc.) are optimized, while adhering to constraints (e.g., density, routing congestion, etc.). In some implementations, floorplanning 112 may also include initial power planning and placement of input, output, macro blocks, and core modules in or on the chip.

A result or output of the floorplanning stage 112 is a floorplan 114. The floorplan 114 may include or indicate, for example, chip dimensions and shape, placement of macro blocks and I/O pads, power grid structure, major routing channels, and/or the like. In some examples, the floorplan 114 is embodied as a design exchange format (DEF) file, which describes the physical layout of the circuit. In some implementations, the floorplanning stage 112 may also output an initial power plan file, such as a UPF file, which specifies the power intent of the design, including power domains, power switches, and other power management strategies. The power plan file may be used for power-aware design, analysis, and optimization, such as during the power planning stage 128 and transistor synthesis stage 132. The UPF file is typically introduced after the initial floorplanning stage 112 and/or placement stage 116, as the power intent becomes more defined and/or refined.

The placement stage 116 involves determining, arranging, and placing the location, position, and/or orientation of standard cells and/or macro blocks within the chip area while meeting design rules. The placement stage 116 may aim to optimize for factors like wire length, routing congestion, timing (including static timing), power consumption, noise, and area utilization. Example indicators or measures of the placement 116 may include routing congestion degree, timing constraints (e.g., set-up time constraints and hold time constraints), maximum voltage drop in the chip, and/or the like.

In some implementations, the placement 116 may be performed automatically using suitable software tools according to the floorplan 114 and/or the other files imported into the physical design flow 110, such as those described previously. For example, the placement stage 116 may operate according to a placement strategy that defines the overarching framework or approach to organizing and positioning components on a chip. Placement strategies can be broadly categorized into flat and hierarchical placement strategies. In flat placement, a circuit (or netlist) is treated as an individual entity, and typically involves placing all units at one time. In hierarchical placement, the chip area is divided into submodules or blocks for step-by-step placement. Typically, hierarchical placement uses a bottom-up or top-down placement approach.

Placement algorithms are specific computational methods used to execute a given placement strategy and/or used to achieve the placement goals. Placement techniques/algorithms are computational processes used to determine the optimal positions of circuit components on a chip while optimizing metrics (e.g., wire length, congestion, etc.) and satisfying design and manufacturing constraints. Thus, placement strategies provide the structural framework, guiding the application of placement algorithms to optimize design performance and manufacturability.

Placement algorithms may be broadly classified as global placement and detailed placement. Global placement uses analytic algorithms, force-directed methods, partitioning-based approaches, and/or image segmentation methods, often combined with geometric techniques for fast calculation. Examples of the analytical algorithms include quadratic placement, nonlinear programming, or convex optimization. Global placement focuses on initial, coarse positioning to optimize metrics (e.g., wire length, congestion, etc.). Detailed placement refines positions to ensure legal and manufacturable layouts within a chosen strategy. Detailed placement uses optimization methods such as dynamic programming, integer linear programming, SA-based placement, greedy optimization, and/or other optimization techniques.

A result or output of the placement stage 116 is a placed netlist 118, which may include the location, position, and/or orientation of each standard cell, custom cell, and/or macro block, as well as updated floorplan information. In some implementations, the placed netlist 118 may be embodied as a DEF file, which may be referred to herein as a placed DEF file 118. In some examples, the placed DEF file 118 is an updated version of the floorplan DEF 112. Additionally or alternatively, the placed DEF file 118 is a separate file from the floorplan DEF 112. Additionally or alternatively, the placement stage 116 may also output an updated SDC file and/or placement reports including, for example, congestion and timing estimates.

The CTS 120 involves creating a network or tree structure, which may be referred to as a “clock tree” or the like, to distribute a clock signal to sequential elements (e.g., flip-flops, etc.) in the circuit to ensure a clock signal is delivered uniformly across the design. The clock tree is a hierarchical structure of buffers and inverters that drive the clock signal. The clock tree may be generated by inserting and sizing clock buffers and inverters along the clock path and may also consider factors such as load balancing, clock gating, and multiple clock domains. The clock tree may be generated based on the gate-level netlist 108, technology library, floorplan 114, and clock specifications. Here, the floorplan 114 may provide the physical locations of cells and flip-flops, and the clock specifications may define clock sources, target clock sinks, and constraints like maximum skew or delay. As an example, the clock specifications may be included in the SDC file. while attempting to minimize clock skew and latency while managing power consumption. Minimizing skew involves attempting to reduce the differences in arrival times between different clocked elements, improving timing performance and overall design reliability.

A result or output of the CTS 120 is a clock tree netlist 122, which may include information about the inserted clock buffers and inverters, the locations of the inserted clock buffers and inverters, and clock routing information that was added during the CTS 120. In some implementations, the clock tree netlist 122 may be embodied as a DEF file, which may be referred to herein as a clock tree DEF file 122. In some examples, the clock tree DEF file 122 is an updated version of the placed DEF file 114 and/or floorplan DEF 112. Additionally or alternatively, the clock tree DEF file 122 is a separate file from the floorplan DEF 112 and/or the placed DEF file 114. Additional outputs of the CTS 120 may include updated timing constraints, clock tree spice netlist, clock tree report(s) indicating skew, latency, power, and/or the like.

The routing stage 124 establishes the physical connections between placed components using metal layers. In some implementations, the routing stage 124 automatically adds wires to connect the placed components while conforming to the design rules, such as those specified by the design constraints file mentioned previously. Routing algorithms or autorouters typically navigate the design rules while optimizing for timing, crosstalk, and manufacturability. The routing algorithms or autorouters may include grid-based routers, gridless routers, graph theory-based routers, negotiation-based routers, and/or the like. The placement 116 and routing 124 (or place and route) of digital circuits may be performed automatically using software tools.

A result or output of the routing stage 124 is a routed netlist 126, which includes detailed routing information for all nets, via locations, metal layer assignments, and/or other like information. In some implementations, the routed netlist 126 may be embodied as a DEF file, which may be referred to herein as a routed DEF file 126. In some examples, the routed DEF file 126 is an updated version of the clock tree DEF file 122, placed DEF file 114, and/or floorplan DEF 112. Additionally or alternatively, the routed DEF file 126 is a separate file from the floorplan DEF 112, the placed DEF file 114, and/or clock tree DEF file 122.

The power planning stage 128 involves designing and optimizing the power distribution/delivery network (PDN) for the chip considering factors such as current density, metal resistance, switching activity, and the like based on, for example, the floorplan 114, placed netlist 118, technology library, and power intent file (UPF) if available. The PDN is a structure that delivers or distributes power (“PWR” or “VDD”) and ground (“GND” or “VSS”) across the chip to prevent voltage drops and ensure adequate power delivery to the macros, standard cells, and other elements in the circuit. Creating the PDN may involve creating and/or arranging power rails, decoupling capacitors, interconnects, and straps. Power grid design may take place after the PDN is created. The power grid design includes a grid of metal wires layered across the chip, forming horizontal and vertical tracks, to distribute power uniformly and reduce resistance and inductance. The power grid design may be a subset of the PDN. The power grid design affects the current and resistance (IR) drop across the chip, which can necessitate specific transistor sizes to maintain performance in low-voltage areas. In some implementations, the power planning stage 128 includes power plan floorplanning to define regions for power and GND pins. In these implementations, the PDN design may take place after the initial power floorplanning.

A result or output of the power planning stage 128 is a power plan file 130, such as a UPF file, which may include detailed power and ground network layout (e.g., the PDN). In some examples, the power plan file 130 may include decoupling capacitor placements, IR drop analysis report(s), power grid verification report(s), and/or the like.

### 1.1. Transistor Synthesis

Transistor synthesis 132 involves converting the gate-level netlist 108 into a transistor-level netlist 134 based on, for example, the gate-level netlist 108, the placed netlist 118, the power plan 130, the technology library, the timing library, the design constraints, and/or other information. In some implementations, the transistor synthesis stage 132 may involve directly mapping from an optimized netlist, such as an AIG output from the logic translation stage, into a transistor-level netlist 134 rather than extracting transistors from the gate-level netlist 108. In some implementations, the transistor-level netlist 134 may also be generated based on parasitic extraction information. Parasitic extraction is an EDA process that calculates parasitic effects in electronic circuits, such as parasitic resistances, parasitic capacitances, and parasitic inductances. These effects are also known as parasitic components, parasitic devices, or parasitics. In some implementations, the parasitic extraction information may be embodied as a standard parasitic format (SPF) file, standard parasitic extraction format (SPEF) file, detailed standard parasitic format (DSPF) file, reduced standard parasitic format (RSPF) file and/or the like.

The transistor synthesis stage 132 typically involves replacing logical gates from the gate-level netlist 108 with their transistor-level implementations, sizing transistors for optimal performance, power, and area, and generating the final layout of individual cells, which may be in the form of a transistor-level netlist 134. In some implementations, when moving from logic gates (e.g., NAND, NOR, FA, etc.) to transistors, the transistor synthesis stage 132 may involve an elaboration in which known transistor(s), or known arrangements of multiple transistors, for each gate are inserted into a netlist. In such implementations, each logic gate may have a known transistor configuration as defined or specified by a standard library and/or the like. For example, NAND and NOR gates may have standard layouts using some combination of PMOS and/or NMOS transistors. When elaborating, high-level gates in a netlist, such as gate-level netlist 108 or an AIG, may be replaced with the predefined transistor arrangements. This process is sometimes automatically performed using suitable EDA tools, where gates are expanded into transistor netlists, such as netlist 134, that match the desired behavior.

In other implementations, the transistor synthesis stage 132 can include mapping logical gates from the gate-level netlist 108 to their transistor-level implementations. For example, individual logic gates in the gate-level netlist 108 may be mapped to a corresponding cell in a standard cell library. Additionally or alternatively, one or more logic gates in the gate-level netlist 108 may be mapped to a corresponding macro block from a macro block library or the like.

The cells and/or macro blocks, such as those included in a standard cell library, a custom cell library, and/or macro block library, may include one or more transistors and/or other hardware elements. The transistors in the cells and blocks may include, for example, field-effect transistors (FET), metal-oxide-semiconductor FET (MOSFET), junction FET (JFET), tunnel FET (TFET), bipolar junction transistors (BJT), insulated-gate bipolar transistor (IGBT), carbon nanotube FET (CNFET), junction-less nanowire transistor (JNT), three-dimensional (3D) transistors, and/or any other type of transistors. The cells and/or macro blocks may also include wires or interconnects between elements and/or other hardware elements such as capacitors, diodes, resistors, inductors, and/or the like.

An initial transistor-level netlist may be the result of the mapping of logic gates in the gate-level netlist 108 to cells, macros, or other combinations of transistors. Then, transistor sizing may take place where the transistor sizes of the transistors in the initial transistor-level netlist are optimized for performance, power, and area. Next, a physical layout of transistors and interconnects is generated from the (re)sized transistor-level netlist to produce a final transistor-level layout, such as the transistor-level netlist 134. The transistor-level netlist 134 may include detailed transistor sizes and connections and internal cell layouts. Additional outputs of the transistor synthesis 132 may include transistor sizing report(s) and updated timing and power analysis report(s).

Various algorithms and techniques can be used for the different aspects of transistor synthesis 132, such as library mapping algorithms (e.g., technology mapping, Boolean matching, pattern matching), transistor sizing algorithms (e.g., logical effort method, convex optimization techniques, transistor sizing for logical effort (TILOS), machine learning techniques, etc.), layout generation algorithms (e.g., compaction algorithms, maze routing, channel routing, etc.), optimization algorithms (e.g., SA, GA, linear programming, etc.), and/or the like.

It should also be noted that, at least in some implementations, other stages in the physical design flow 110 may interact with or otherwise influence transistor synthesis 132. For example, floorplanning 112 may sets the overall constraints and environment for transistor synthesis 132; placement 116 may have a bidirectional relationship with transistor synthesis 132 where each stage influences the other iteratively; coordination between the CTS 120 and transistor synthesis 132 may be performed to meet timing and power goals; and parasitic information provided by the routing stage 124 may be used to guide transistor sizing. The transistor-level netlist 134 may be embodied as a simulation program with IC emphasis (SPICE) file, Verilog-A file, electronic design interchange format (EDIF) file, circuit description language (CDL) file, or a proprietary formats.

Although not shown by FIG. 1, a physical verification process, sometimes referred to as “sign-off”, may take place after transistor synthesis 132. The physical verification process may involve verifying various aspects of the IC layout 160 via one or more EDA software tools to ensure correct electrical and logical functionality and manufacturability. The verification processes may include, for example, design rule checks (DRC), layout versus schematic (LVS) checks, exclusive OR (XOR) checks, antenna checks, and electrical rule checks (ERC). The tapeout is the final design stage for the IC before being sent for manufacturing. The tapeout is specifically the point at which the graphic for the photomask of the circuit is sent to the fabrication facility 812. The final output of the physical design process is usually a graphic design system (GDSII) or open artwork system interchange standard (OASIS) file, which is used for manufacturing by the foundry 812, along with various report files from the verification and sign-off such as final timing, power, and area reports, sign-off DRC reports, and/or LVS reports.

### 1.2. Transistor Placement

Aspects of the present technology include Eulerpath-based transistor placement. Transistor placement determines the physical arrangement of transistors within a cell, usually with a goal of optimizing area, performance, and power while ensuring adherence to design rules. The transistor placement process usually involves aligning transistors to minimize diffusion breaks, grouping PMOS and NMOS transistors for efficient power and ground connections, and arranging them to facilitate routing of signals. In some aspects, transistor placement may occur during the placement phase 116 or during a custom layout design process. In some examples, the transistor placement may be used for standard cells and/or custom designed cells. For standard cell libraries, transistor placement is standardized to allow reuse across multiple circuit designs. In custom layouts, transistor placement is typically manually or semi-automatically adjusted to meet specific design requirements.

The placement of transistors may directly impact the overall performance, power consumption, and area of a chip. Therefore, optimizing transistor placement is beneficial for most circuit designs. For example, an optimized transistor placement may minimize diffusion breaks, which reduces parasitic capacitance and resistance, thereby improving signal timing and reducing power dissipation. Additionally, optimized transistor placement can reduce the total wire length required for interconnections, minimizing routing complexity and congestion and improving overall design closure. Furthermore, optimized transistor placement can reduce the overall area occupied by standard cells or custom cells/blocks, thereby achieving higher transistor density and improving area utilization, allowing for more compact layouts and potentially reducing manufacturing costs. Moreover, strategic transistor placement can enhance thermal distribution and power delivery, leading to improved reliability and reduced chip hotspots.

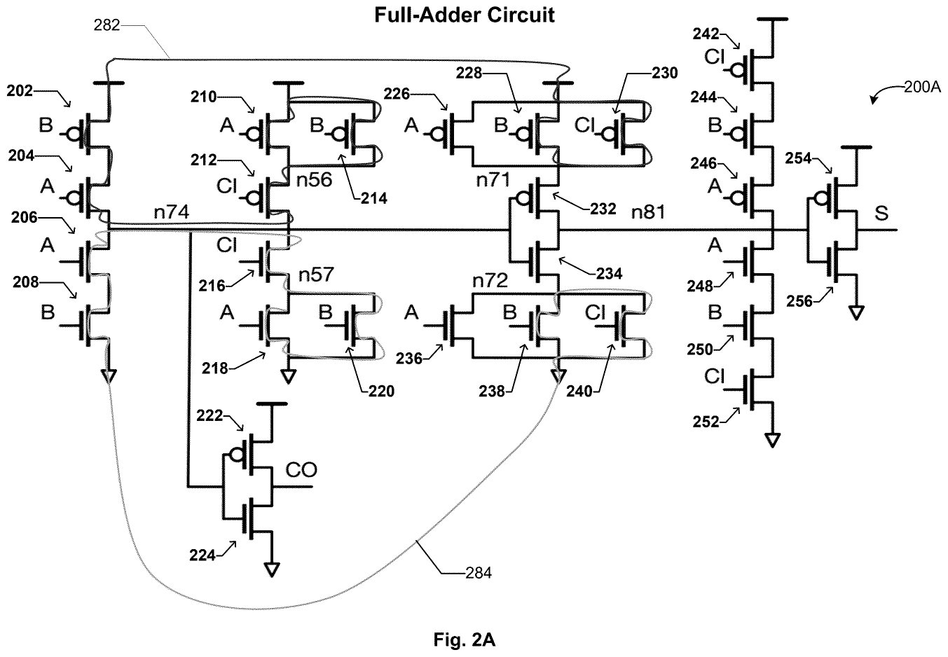

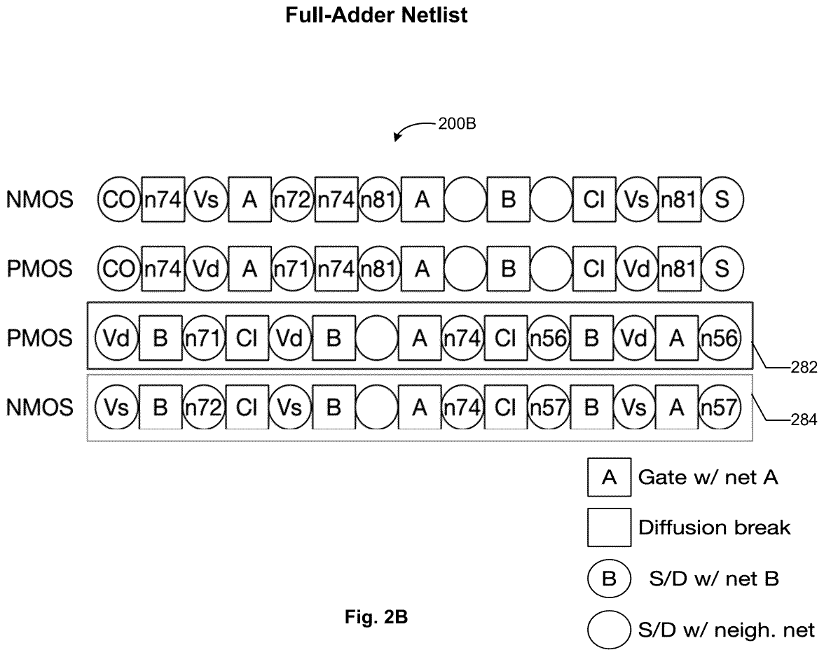

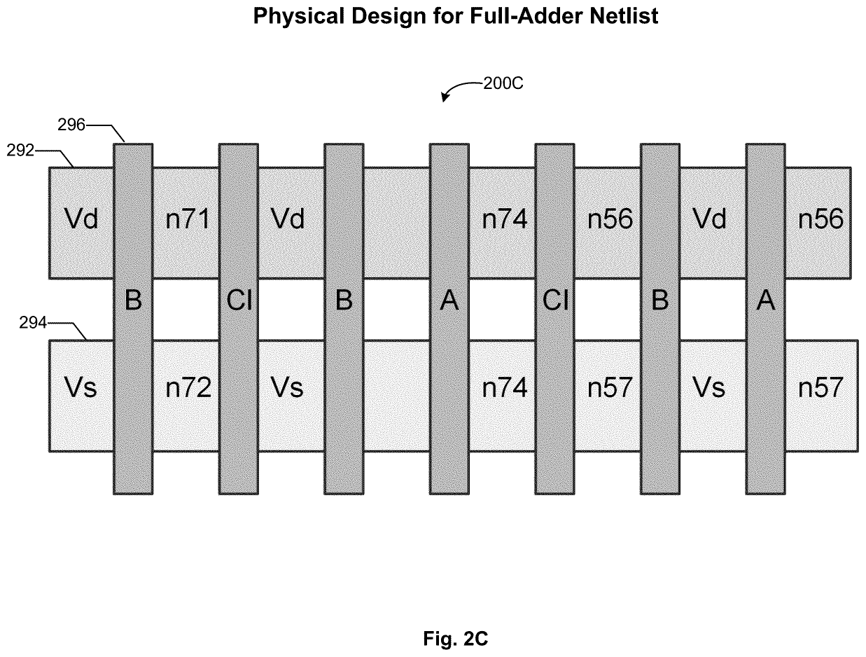

Despite the various benefits, transistor placement optimization faces several challenges and drawbacks. For example, achieving optimal placement may involve trade-offs between conflicting objectives, such as minimizing wire length versus ensuring design rule compliance or maintaining thermal balance. Additionally, typical transistor placement optimization processes are computationally intensive, such as those used for large-scale designs with numerous transistors, which can make optimization algorithms slow and resource-intensive. Furthermore, many conventional custom layout transistor placement optimizations may require manual optimization, which can be time-consuming and prone to designer bias or errors. Moreover, as technology scales to smaller nodes, the growing complexity of design rules and the increasing significance of parasitics add further constraints, making it increasingly difficult to achieve ideal placements without extensive iterations of optimization algorithms. The Eulerpath-based transistor placement of the present technology addresses such shortcomings. Aspects of the Eulerpath-based transistor placement are discussed in more detail with respect to FIGS. 2A-7.

### 2. Eulerpath-based Transistor Placement

The present technology is related to placement of a relatively large number of transistors when preparing an IC design, which may take place during the physical design phase 110 of EDA, such as during the placement stage 116 or during custom cell design. An example is shown by FIGS. 2A, 2B, and 2C. FIG. 2A shows an example full-adder netlist 200A, FIG. 2B shows a corresponding spatial representation 200B of the netlist 200A, and FIG. 2C shows a corresponding physical design/layout 200C of the netlist 200A and spatial representation 200B in accordance with aspects of the present technology.

Referring now to FIG. 2A, the full-adder netlist 200A includes a set of p-channel metal-oxide-semiconductor (PMOS) transistors 202, 204, 210, 212, 222, 226, 228, 230, 232, 242, 244, 246, and 254, and a set of n-channel metal-oxide-semiconductor (NMOS) transistors 206, 208, 216, 218, 220, 224, 234, 236, 238, 240, 248, 250, 252, and 256.

The full-adder netlist 200A also includes a PMOS network and an NMOS network. The PMOS network is highlighted by PMOS Eulerpath 282, and includes transistors 202, 204, 210, 212, 214, 226, 228, and 230. Each PMOS transistor in the PMOS network is connected in a sequence determined by the Eulerpath 282. The transistors 202, 204, 210, 212, 214, 226, 228, and 230 may be connected to a high voltage source to pull the output nodes high when their inputs are low. The NMOS network is highlighted by NMOS Eulerpath 284, and includes transistors 206, 208, 216, 218, 220, 236, 238, and 240. The transistors in the NMOS network are connected to GND and configured to pull the output nodes low when their inputs are high. The NMOS network is structured to match the PMOS network with a complementary arrangement. Therefore, the NMOS network complements the PMOS network, and thus, the full-adder netlist 200A may be a complementary metal-oxide semiconductor (CMOS) design.

Each of the nets, such as nets n74, n56, n57, n71, n72, and n81, may refer to a connection, such as a contiguous piece of metal, that leads to the same voltage for every element connected to it. Additionally or alternatively, the nets may be internal nets, which may refer to a signal or connection within a digital circuit that are neither primary inputs nor primary outputs, and may represent intermediate results of logic operations. Additionally or alternatively, an internal net, may refer to the connections that link internal components within a circuit and/or the connections between logic gates within a circuit. In the example of FIG. 2A, the nets n74, n56, n57, n71, n72, and n81 may represent interconnection points between transistors in the PMOS and NMOS networks. The nets may carry intermediate voltages that depend on the logic inputs, and which may influence the output signals.

The full-adder netlist 200A processes inputs A, B, and carry-in (CI) to produce the outputs sum(S) and carry out (CO). The PMOS network (highlighted by PMOS Eulerpath 282) pulls the outputs S and/or CO high and the NMOS network (highlighted by PMOS Eulerpath 284) pulls the outputs S and/or CO low. The PMOS transistors conduct when their gate input are low (logic 0), and pull the nodes, such as nets n74, n56, n57, n71, n72, and n81, high because the PMOS transistors are connected to the power supply. The NMOS transistors conduct when their gate input is high (logic 1), and pull the nodes, such as nets n74, n56, n57, n71, n72, and n81, low because the NMOS transistors are connected to ground.

Referring now to FIG. 2B, which shows a spatial representation 200B corresponding to the full-adder netlist 200A of FIG. 2A. The spatial representation 200B of FIG. 2B shows how the Eulerpath(s) will be laid out in a standard cell or custom cell design. In the spatial representation 200B, squares may represent diffusion breaks. Diffusion breaks may break the continuity in a diffusion layer, which may isolate different transistor segments. The label in each square may represent the net or signal connected to a gate of a transistor. For example, a square with the label “A” may represent a gate of a transistor connected to signal/input A, a square with the label “B” may represent a gate of a transistor connected to signal/input B, a square with the label “CI” may represent a gate of a transistor connected to signal/input CI, a square with the label “n74” may represent a gate of a transistor connected to net n74, and so forth.

Additionally, circles may represent sources and/or drains connected to a neighboring or adjacent net. The label in each circle may represent a neighboring net connected to a source and/or drain of a transistor. For example, a circle labeled with “Vs” may have a source or drain connected to ground, a circle labeled with “Vd” may have a source or drain connected to the power source, a circle labeled with “n72” may have a source or drain connected to net n72, and so forth.

Referring now to FIG. 2C, which shows a physical layout 200C corresponding to a portion of the spatial representation 200B, such as the bottom row of the spatial representation 200B in FIG. 2B. In this example, PMOS layer 292 may be based on the PMOS Eulerpath 282, NMOS layer 294 may be based on NMOS Eulerpath 284, and gate layers 296 may be based on the gates shown by FIGS. 2A and 2B. Note that not all gate layers 296 include a reference label in FIG. 2C.

An aspect of the present technology is to design the physical layout for transistors, including both PMOS and NMOS transistors, placed in contiguous rows. The placement of transistors may be made more compact based on whether the source, drain, and/or gate terminals of a set of transistors is assigned to the same net, including nets such as power (“PWR”, “VDD”, or “V_{dd}”) and ground (“GND”, “VSS”, or “Vₛₛ”). If the source or drain terminals of at least two transistors belong to the same net, then the at least two transistors can be placed more compactly by diffusion sharing. Diffusion sharing is a layout optimization technique where adjacent transistors share a common diffusion region to reduce area, routing congestion, and parasitic capacitance. Additionally, gates can be aligned such that they can be connected by a vertical poly line.

A “net” may refer to a connection, such as a contiguous piece of metal, that leads to the same voltage for every element connected to it. Additionally or alternatively, a net, such as an internal net, may refer to a signal or connection within a circuit that are neither primary inputs nor primary outputs, and may represent intermediate results of logic operations. Additionally or alternatively, an internal net, may refer to the connections that link internal components within a circuit and/or the connections between logic gates within a circuit.

As mentioned previously, the present technology attempts to maximize diffusion sharing between transistors. The present technology attempts to find a coverage of a graph by searching a netlist for suitable paths. Here, a chain of transistors (e.g., NMOS or PMOS) has a path referred to as an Eulerpath, which may also be referred to as an Eulerian path or Eulerian trail. Eulerpaths can be “peeled off” the graph to decrease the problem size for better asymptotic scaling. This approach is different than satisfiability (SAT)-based approaches.

Typically, an Eulerpath is a path or trail in a graph that visits every edge exactly once. An Eulerpath may pass through a vertex more than once, but it cannot reuse an edge. For an Eulerpath to exist, the graph (i) must be connected, which means that every vertex is reachable from every other vertex, and (ii) must have exactly zero or two vertices of odd degree. Here, the degree is the number of edges connected to a vertex. A Eulerian circuit, or Euler circuit, is a type of Eulerpath that starts and ends at the same vertex. A graph is or has an Euler circuit if the graph is connected and all vertices have an even degree.

In aspects of the present technology, an Eulerpath is a contiguous path in a netlist hyper-graph that can be placed as an individual sequence of diffusion-sharing transistors. Finding a coverage of the netlist, such as netlist 200A (or spatial representation 200B), 108, 118, 112, 126, and/or 134, with the longest possible Eulerpaths is equivalent to finding a placement with fewer diffusion breaks, resulting in smaller overall circuit area. PMOS and NMOS Eulerpaths, such as PMOS Eulerpath 282 and NMOS Eulerpath 284, can be gate-aligned such that the gate poly physical design becomes trivial.

For example, in FIG. 2B, the gate nets are aligned between the NMOS and PMOS rows. When the gates are aligned between the NMOS and PMOS rows, some or all technologies allow the aligned gates to be connected with a vertical line in the polysilicon gate material. Since this is the gate material itself, routing in this way typically does not require a large amount of routing resources. Gate misalignment typically makes designs unrouteable or routing inefficient. Additionally, routing resources can be conserved by vertically aligning source/drain contacts between PMOS and NMOS transistors. For example, as shown by FIG. 2B, the source/drain contacts are aligned between the NMOS and PMOS rows. When the source/drain contacts are aligned between the NMOS and PMOS rows, some technologies allow the aligned source/drain contacts to be connected using middle-of-line routing material, which can conserve routing resources. Thus, an aspect of the present technology includes identifying Eulerpaths within a given circuit design and scoring each identified Eulerpath based on how ‘good’ their routing will be based on gate-alignment, source/drain alignment, and/or other factors.

In some aspects, after the Eulerpaths are formed or otherwise identified, each Eulerpath may be scored according to the number of gates that align between the PMOS and the NMOS rows (or halfrows). The design may be considered ‘more routable’ if some or all gates are aligned between the PMOS and the NMOS rows (or halfrows). Thus, in some aspects, if transistors have aligned gates and a diffusion (ohmic) contact, then their gates can be connected.

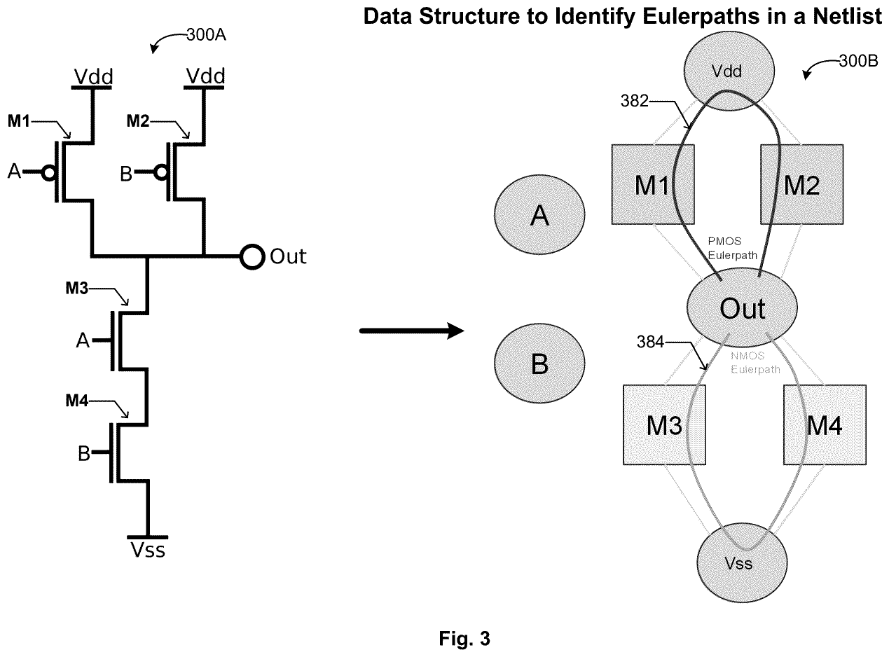

FIG. 3 shows an example circuit 300A and example data structure 300B in accordance with the present technology. Circuit 300A may be a CMOS NAND gate, which takes two inputs A and B and produces an output Out. The PMOS transistors M1 and M2 are connected in parallel between Out and the power supply (Vdd), and the NMOS transistors M3 and M4 are connected in series between Out and the ground (Vss). The PMOS transistors M1 and M2 conduct when their gate input is at logic 0. Since PMOS transistors M1 and M2 are connected in parallel, the output Out is connected to Vdd (logic 1) if either input A or input B is at logic 0. The NMOS transistors conduct when their gate input is at logic 1. Since NMOS transistors M3 and M4 are connected in series, the output Out is connected to Vss (logic 0) only when both A and B are at logic 1.

The data structure 300B may be a data structure, such as an undirected graph, which may be used by the system to identify Eulerpaths in a netlist. For example, the circuit 300A may be converted into the data structure (undirected graph) 300B. Each node in the undirected graph may represent a transistor or net. For example, the square nodes in graph 300B may represent respective transistors M1, M2, M3, and M4 from circuit 300A, and oval nodes in graph 300B may represent respective nets, such as Vdd, Out, and Vss from circuit 300A. Each node may contain metadata. For example, the transistor nodes may contain a gate net identifier (ID), net nodes may contain a net node ID, and/or the like. Each node may include other types of metadata such as, for example, electrical characteristics, orientation information, the gate net, transistor type (e.g., PMOS, NMOS, etc.), the number of fins the transistor has, a threshold voltage, and/or the like.

The edges between transistor and net nodes in graph 300B may represent where there are ohmic (source/drain) connections. Eulerpaths can be found or identified by (i) selecting a PMOS or NMOS subgraph; and (ii) starting at a net node, progress through a transistor node, then progress through a net node, and so forth until an Eulerpath is completed. In one example, the PMOS subgraph may be selected, and the PMOS Eulerpath 382 may be identified by starting at net node Out, then progressing through transistor node M1, then progressing through net node Vdd, then progressing through transistor node M2, and then progressing through net node Out. In another example, the NMOS subgraph may be selected, and the NMOS Eulerpath 384 may be identified by starting at net node Out, then progressing through transistor node M3, then progressing through net node Vss, then progressing through transistor node M4, and then progressing through net node Out.

In some aspects, other types of graph representations or data structures may be used. However, some types of graph representations or data structures may suffer from drawbacks, such as losing too much information. For example, some types of graph representations net nodes and transistor edges may not allow multiple transistors to have the same source/drain. In another example, some types of graph representations transistor nodes and net edges may lose transistor orientation information (e.g., whether the drain and source is flipped or not), and the like.

Additionally, the number of Eulerpaths may grow very quickly with circuit size. In particular, the number of possible Eulerpaths in a PMOS subgraph or an NMOS subgraph grows exponentially with the number of edges on net nodes, which is related to the number of transistors in the subgraph because transistor stacks are usually limited to three in series. Once the number Eulerpaths from the PMOS subgraph (Nₚ) and the number of Eulerpaths from the NMOS subgraphs (Nₙ) have been extracted, determined, or identified, the number of alignments between the PMOS and NMOS Eulerpaths is Nₙ*Nₚ, which may be a square of the number of Eulerpaths. Thus, the number of possible NMOS +PMOS Eulerpath-pairings may grow as a square function as the number of transistors increases. As an example, for a design that included 66 transistors, there are about 10¹⁵ possible pairings of Eulerpaths with 18 transistors.

An example algorithm for this Eulerpath-based transistor placement may be described as follows, in view of the example circuit 300A and the example paths 300B. The algorithm may be implemented by one or more processors of a computing system, such as described herein.

First, a netlist, such as netlist 200A or any other netlist discussed herein, is transformed or converted into a graph representation, such as an undirected graph or an adjacency matrix. Here, nodes in the graph represent either transistors or nets. Net nodes contain respective net IDs, and potentially other metadata such as electrical information and/or the like. Transistor nodes contain respective transistor metadata (e.g., a gate net ID, orientation information, electrical information, etc.). Ohmic contacts are source or drain contacts. Edges occur between transistor and net nodes where there are ohmic (source/drain) connections. The gate contacts may be ignored at the point.

Second, the system searches for Eulerpaths. This can be done by separately searching subgraphs containing PMOS transistors and subgraphs containing NMOS transistors. The Eulerpath search can be performed separately for each subgraph and can be performed in both directions. By way of example, as noted previously, the system may start at an initial net node, traverse through a transistor node, subsequently traversing through another net node, and iteratively continuing this sequence until returning to the initial net node. Eulerpath searches may be run in parallel, for instance using as many processors as possible or that are otherwise available. The processors may be contained in a single computing system, such as one of computing devices 802, 804, 806, or 808 in FIGS. 8A-8B, or may be distributed across multiple computing systems, such as any number and combination of computing devices 802, 804, 806, or 808 in FIGS. 8A-8B.

Third, the system takes the Eulerpaths and tries to align them, resulting in the physical design. While true optimality may be unfeasible due to the sheer number of possible Eulerpaths to evaluate, various heuristics (e.g., scoring metrics, etc.) can be employed to prune the search space. This may involve peeling off “good-enough” Eulerpaths greedily from the graph until the size becomes manageable for performing more exhaustive searches.

For example, heuristics can be developed to identify gate-aligned Eulerpaths, wherein the system looks for gate-aligned pairings when the circuit is a certain size, or larger than or equal to a threshold size. Such heuristics may be useful because gate misalignment in most technologies may lead to unrouteable designs or designs with inefficient routing, especially if the Eulerpaths are relatively long. Therefore, for most technologies if the netlist contains a large number of transistors, the system may identify gate-aligned Eulerpaths as the best Eulerpaths.

Additionally or alternatively, some heuristics may involve assigning scores to each identified Eulerpath and retaining the highest-scoring Eulerpaths. Scores can be based on factors such as an amount of diffusion sharing, a number of gate-alignments, a number of source/drain-alignments, a number of parallel tracks, and/or other factors. Individual metrics can be scored separately, then combined, averaged, or otherwise aggregated. For example, one score may represent the number of gate-alignments, while another score may represent the source/drain-alignments, with all scores/metrics contributing to a final score. Additionally or alternatively, an objective function or optimization algorithm can be used to evaluate and assign scores to each identified Eulerpath by quantifying various factors, such as those mentioned previously, and optimizing for desired design criteria.

For heuristics involving determining whether all of the gates are aligned, a ‘good’ score may be assigned if aligned, otherwise a ‘bad’ score is assigned if not aligned. Similar scoring methodologies can be applied for heuristics for scoring the amount diffusion sharing in Eulerpath, scoring gate-alignments, scoring source/drain-alignments (may be more applicable for newer fab techniques), and/or the number of parallel tracks. In the latter case, most technology have many tracks (the number of parallel metal wires in a metal layer in between the power rails), so a criterion may be whether more tracks are needed than the maximum number of tracks supported by the technology.

In some aspects, the heuristics may be technology dependent (e.g., including contact over gate or contact over diffusion approaches). For instance, if it would be hard to route without alignment, then a higher good score may be applied if there is alignment of ohmic contacts. The design rules and any other limitations of the PDK for the technology may also be accounted for in such heuristics. The final result should have both good placement and be routable.

Fourth, the process collects the best scoring Eulerpaths, then peels them out of the graph. This reduces the graph size, and can be done iteratively to reduce the graph until it disappears. It can be seen that the goal is not to evaluate all paths. Rather, the process may involve limiting the length of Eulerpaths, although this may still involve evaluating several billion PMOS/NMOS path pairings.

Thus, while the algorithm may be considered “greedy”, it is not required to only use the best Eulerpaths. Rather, the process scores the combined number of Eulerpaths, which encompass all of the transistors. The system generates a list of Eulerpaths, where each path contains PMOS and NMOS transistors. In some aspects, the system attempts to get the same number of PMOS and NMOS of transistors in every Eulerpath in which they are aligned. However, for bigger circuits, the criteria can be made more restrictive to pare down. For instance, the system may start with searching for only gate-aligned paths, and only look for nodes with gate-aligned sequence. Then, the system may traverse the graph to search for transistors with the same sequence.

One goal is to smartly prune down the search space while retaining best possible paths. In some aspects, the system may be able to relax the criteria. For instance, the approach may start with only gate-aligned paths, since there are typically fewer of those and they are usually the paths that score high. Then, as the circuit solution becomes smaller, then the criteria can be relaxed. Additionally or alternatively, the “search recipe” may be developed empirically for each technology.

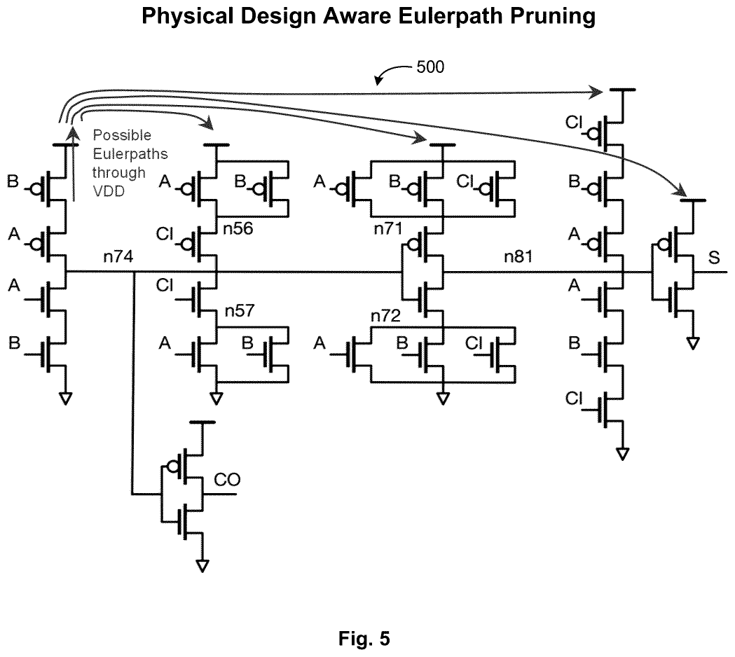

Another aspect of the technology involves Eulerpath pruning based on physical design awareness. FIG. 5 illustrates an example netlist 500 with possible Eulerpaths through V_{dd}. The netlist 500 may be a full-adder circuit, such as full-adder netlist 200A in FIG. 2A. In this example, the power grid connects to numerous transistors. An Eulerpath that connects to V_{dd} or Vₛₛ, can exist anywhere in the netlist, which can result in a combinatorial explosion of possible Eulerpaths. While there is a desire to minimize half-perimeter wirelength (HPWL) globally, there may be a power grid concern because the power grid of the IC typically connects to many transistors. For instance, the Eulerpath search is unaware of HPWL, and thus, paths exist that can go through the power rails and end up anywhere in the design, connecting two transistors that globally should be very far apart.

Thus, not all such paths make practical sense if a goal is to reduce interconnect length. Therefore, the system may anneal a transistor placement with a wirelength objective (e.g., an HWPL constraint). Here, one goal may be a pre-placement that globally optimizes HPWL. This can be achieved by SA or any other method, for example, electrostatics based analytical placement. In the pre-placed netlist, the distance between transistor pairs can then be measured and paths that are longer than some distance from each other can be pruned. SA is a probabilistic technique to approximate the global optimum of a function. Here, the process may store the distance of each transistor pair, and ignore Eulerpaths that would connect far-away transistors through the power grid connection. The distance may be associated with buffering. A maximum physical distance may depend on the type of circuit or circuit architecture.

Some aspects of the present technology involve incorporating logic synthesis-awareness into the system. For example, as alluded to previously, logic synthesis may involve mapping a Boolean function to a set of transistors, which eventually leads to obtaining a netlist including transistors, such as transistor-level netlist 134. The synthesis may automatically lead to stages of transistors where all transistor are connected to the output line in the center. The full adder in FIGS. 2A and 5 has two stages, a first stage that has an output at net n74 and a second stage that has an output at net n81. A pre-placement that clusters these transistor states together may lead to much better pruning, which means that transistors in a stage want to be close together in a physical design.

Fifth, once the system has the selected the set of Eulerpaths, they need to be placed on the chip. Placement may be similar to standard cell placement 116 or the like, but the process may perform routing on the transistor level, rather than on the standard cell level. In some cases, there may be more pin accessibility problems with transistor-level placement than standard cell placement. According to one aspect, an annealing approach may be done to reduce wire length (HPWL). However, electrostatic placement, SA, or other approaches may alternatively be utilized.

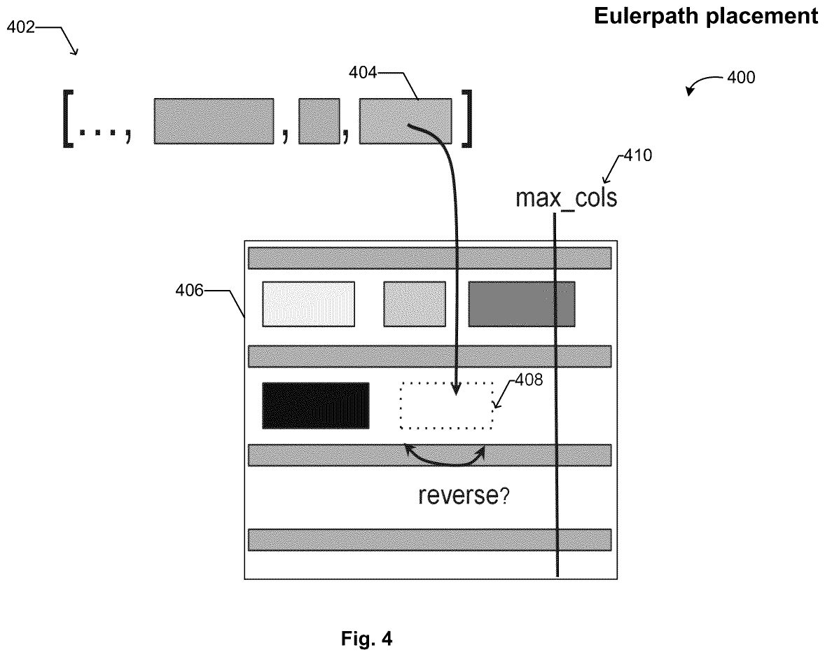

FIG. 4 illustrates an exemplary annealing placement approach 400, which involves using the following sequence of annealing actions. First, start with a list of Eulerpaths 402, which includes a set of Eulerpaths 404. Note that not all Eulerpaths 404 are labeled in FIG. 4. In this example, the list 402 may be an adjacency list or an adjacency matrix. Here, each Eulerpath 404 comprises a set of transistors and/or a set of nets. Second, place a Eulerpath 404 or a reversed Eulerpath from the list 402 at a current position 408 in the chip canvas 406. Third, advance the current position 408 by the length of the placed Eulerpath 404. Fourth, if the current position 408 (or a portion thereof) extends further than maximum column (max_cols) 410, advance to the next row and reset the position 408. Fifth, after all of the Eulerpaths in the list 402 are placed, evaluate HPWL and keep the placement if it is better than the previous placement. Sixth, anneal the order and/or reversal of the Eulerpaths 404 in the list 402.

Once the placement has been done, the process is effectively complete. However, router testing can be performed to evaluate and refine the placement for a specific technology. Router testing can be performed using techniques such as A* routing, combinatorial routing, or others. A* is a standard algorithm in VLSI design for routing pairwise connections between nets. After individual nets are routed, intersections often occur, which are typically resolved using a negotiated congestion algorithm. This approach is standard in VLSI design, with the main distinction being that routing is performed at the transistor level.

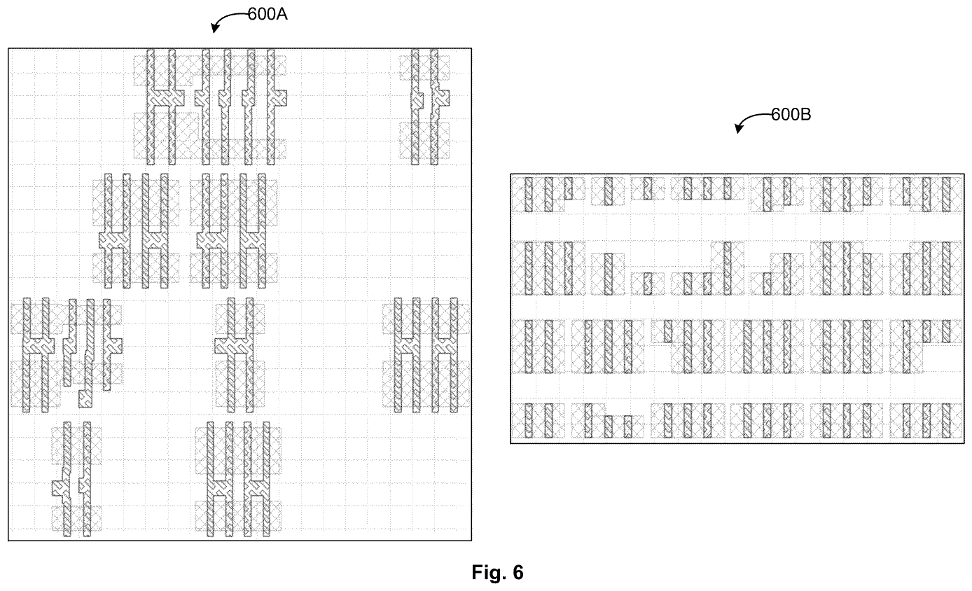

Testing has shown significant benefits to the Eulerpath approach as described. For instance, FIG. 6 visually illustrates the physical size difference between a standard cell 600A having 66 total transistors and the Eulerpath placement cell 600B of the present technology. The Eulerpath placement cell 600B used the same netlist and width constraints as the standard cell design 600A The Eulerpath placement cell 600B includes the following metrics: 75 columns, 5 PMOS and NMOS Eulerpath pairs (EP), 13.2 transistors per Eulerpath (T/EP), and 29 seconds. The time (e.g., 29 seconds in this example) refers to the time for a single-threaded run. The standard cell 600A design includes the following metrics: 83 columns, 9 EP, and 9.2 T/EP. Here, the fewer the number of columns, the better for placement in a single row. Note that one transistor spans 3 columns for the source, gate and drain in this example.

### 3. Example Methods

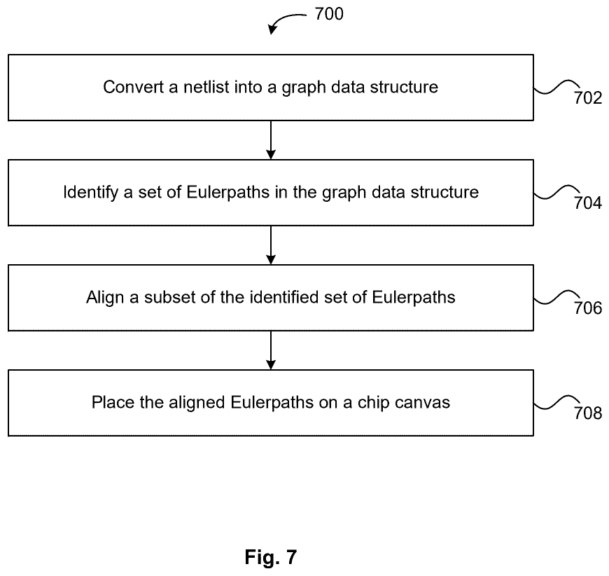

FIG. 7 shows an example Eulerpath transistor placement process 700, which may be performed using a suitable EDA tool operated by a computing device, such as any of the computing systems 802, 804, 806 of FIGS. 8A-8B.

Process 700 begins at operation 702 where the computing device converts a netlist into a graph data structure, wherein each node in the graph data structure represents either a transistor in the netlist or a net in the netlist. At operation 704, the computing device identifies a set of Eulerpaths in the graph data structure. At operation 706, the computing device aligns a subset of the identified set of Eulerpaths. At operation 708, the computing device places the aligned Eulerpaths on a chip canvas. After performing operation 708, process 700 may end or repeat as necessary.

### 4. Example System

FIGS. 8A-8B depict an example of a system 800 configured to implement the technology discussed herein. In particular, FIG. 8A is a block diagram and FIG. 8B is a functional diagram, of an example system 800 that includes a plurality of computing devices 802, 804, 806 and a storage system (e.g., one or more databases) 808 connected via a network 810. System 800 may also include a fabrication facility 812 (also referred to as “fab 812”) that is configured to produce circuitry designed according to the processes described herein.

Computing device(s) 802 may represent one or more servers and/or other physical and/or virtual computing device(s) that provide access to a pool of physical and/or virtual resources, data, services, and/or programs to other computer device(s), such as computer device(s) 804 and/or 806, over a network, such as network 810. The server(s) 802 may be implemented as web servers, application servers, email servers, file and/or storage servers, and/or run virtual machines (VMs), containers, applications, and/or other executable code. The various servers 802 discussed herein can be embodied as rack servers, tower servers, blade servers, microservers, converged infrastructure, hyper-converged infrastructure (HCI), edge servers, and/or the like. The servers 802 may represent a cluster of servers, a load balanced server farm, a cloud computing service/architecture, an edge computing network/architecture, and/or other grouping or pool of servers, which may be located in one or more datacenters and/or other sites. Additionally, the servers 802 may be interconnected with one another using any suitable networking and/or interconnection technologies, such as Ethernet, fiber channel, data center interconnect, virtual extensible LAN, InfiniBand, switch fabrics, and/or the like.

In some examples, computing devices 802 may exchange information with different network nodes for the purpose of receiving, processing, and transmitting the data to and from other computing devices. Here, the server(s) 802 may handle requests from clients such as computing devices 804, 806 and/or fab 812 (or computing devices therein), processes the requests, and returns appropriate responses via the network 810. In this regard, the server(s) 802 may provide one or more services to one or more clients. Such services may communicate with each other and/or with one or more of computing devices 804, 806 and/or fab 812 (or computing devices therein) via one or more software interfaces, such as application programming interfaces (APIs), application binary interfaces (ABIs), remote procedure calls (RPCs), and/or other interfaces.

In the example of FIGS. 8A-8B, computing device 804 is depicted as a workstation and computing device(s) 806 is depicted as a laptop. However, the client devices 804, 806 could be other types of user devices, such as smartphones, tablet computers, desktop computers, wearable devices, video game consoles, networked appliances, drones, robots, single-board computers, plug computers or dongles, and/or any type of computing devices. Additionally or alternatively, the computing devices 802, 804, 806 may be implemented as part of fab 812 and/or any other system discussed herein.

Fab 812 may be a foundry, factory, manufacturing plant, or other location where semiconductor device fabrication takes place to produce semiconductor structures, such as ICs and the like. For example, fab 812 may include various types of fabrication equipment, robots, computing systems, and/or other systems/devices configured to perform photolithographic and physico-chemical processes during which semiconductor devices are created on a wafer using various semiconducting material(s). Such semiconductor manufacturing processes may include (not in any particular order), for example, wafer preparation (e.g., ingot growth, wafer slicing, wafer cleaning, wafer polishing, etc.), oxidation, photolithography (e.g., photoresist application, mask alignment, UV light exposure, etc.), etching (e.g., wet chemical etching, dry etching, mechanical grinding, chemical mechanical planarization (CMP), etc.), ion implantation or doping, annealing (e.g., spike annealing, drive-in annealing, etc.), deposition (e.g., atomic layer deposition, molecular layer deposition, chemical vapor deposition, physical vapor deposition, conformal film deposition, etc.), planarization (e.g., CMP, etc.), metal layer deposition and patterning, passivation, die preparation, IC packaging, IC testing, and/or other processes. Additional or alternative PCB and/or semiconductor manufacturing techniques may be used, such as silk-screen printing, photoengraving, PCB milling, laser resist ablation, laser etching, plasma exposure, thermal treatments (e.g., rapid thermal processing (RTP), furnace annealing, laser annealing, thermal oxidation, etc.), plasma ashing, epitaxy, and/or the like.

As shown in FIG. 8B, each of the computing devices 802, 804, and 806 may include one or more processors, memory, data and instructions. Some or all of the computing devices 802, 804, and 806 may also include communication interfaces, output device(s), and/or input device(s).

The one or more processors may include one or more general-purpose processors, which may be processor(s) designed to perform a wide variety of tasks and/or processor(s) capable of running a broad range of applications and programs efficiently. Additionally or alternatively, the one or more processors may include one or more special-purpose processors, which may be processor(s) designed to perform specific tasks or functions with relatively high efficiency and/or processor(s) optimized for particular applications or workloads. By way of example, the one or more processors may include any number and/or combination of: central processing units (CPUs), graphical processing units (GPUs), accelerated processing units (APUs), microcontrollers, neural processing units (NPUs), tensor processing units (TPUs), hardware accelerators, p-bit devices, application-specific ICs (ASICs), field-programmable gate arrays (FPGAs), digital signal processors (DSPs), network processors, data processing units (DPUs), quantum processing units (QPUs), crypto-processors, programmable logic devices (PLDs), and/or any other hardware-based processor. References to a processor or processor(s) should be understood to include references to a single processor or a collection of processors that may or may not operate in parallel.

The memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as random access memory (RAM), read-only memory (ROM), non-volatile RAM (NVRAM), flash memory, solid-state storage, memory cards, magnetic disk storage mediums, optical storage mediums such as CDs and DVDs, as well as other write-capable and read-only memories. Systems and methods may include different combinations of the foregoing, whereby different portions of the instructions and data are stored on different types of media.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance. The instructions may be stored in additional or alternative formats. The flows shown by FIG. 1, and the process shown by FIG. 7, illustrate examples of algorithms that may be implemented according to such instructions or programs.

The data may be retrieved, stored or modified by one or more processors in accordance with the instructions. The data may also be formatted in any computing device-readable format. For instance, although the claimed subject matter is not limited by any particular data structure, the data may be stored in computing device registers, in relational and/or non-relational databases having a plurality of different fields and records, electronic documents (e.g., HTML, XML, JSON, Protobufs, etc.) or flat files, HDL information, GDSII information, and/or the like. The data may also be formatted and/or stored in any computing device-readable format.

The computing devices may also include a communication system having one or more wired or wireless connections to facilitate communication with other computing devices of system 800 and/or the fabrication facility 812. The communication interfaces may include interconnection or network interface controllers, components, or other suitable devices to communicate with one or more peripheral devices such as input and/or output device(s), one or more databases such as database(s) 808, and/or network nodes via one or more networks such as network 810. For example, the communication interfaces may include wired communication components (e.g., for coupling via USB, Ethernet, fiber optics, and/or the like), cellular communication components, wireless local area network (WLAN), short range communication components, NFC components, and other communication components. It should be noted that the computing devices 802 may also be connected to network 810 and/or to one another via an external communication interface, such as a switch fabric, gateway node, and/or the like.

The computing devices may include all of the components normally used in connection with a computing device such as the processor and memory described above as well as a user interface having one or more input devices (e.g., one or more of a button, mouse, keyboard, touch screen, touch pad, gesture input, dial, switch, microphone, sensors such as sensors including cameras and the like, etc.), various output devices (e.g., electronic display having a screen or projector, speakers, actuators or haptic feedback devices, etc.), and/or other devices/components to enable user interaction with the computing devices.

The various computing devices may communicate directly or indirectly via one or more networks, such as network 810. The network 810 and any intervening nodes may include various configurations and protocols including wired protocols (e.g., Ethernet, etc.), fiber optics networks, cellular communication protocols (e.g., 3GPP) LTE, 3GPP 5G/NR, WiMAX, GSM, etc.), WLAN communication protocols (e.g., WiFi®, Infrared Data Association (IrDA), P2P, etc.), short range communication protocols (e.g., Bluetooth™, WiFi-direct, Miracast, ANT+, Z-Wave, Zigbee®, etc.), the Internet (e.g., including HTTP, TCP/IP, and/or other Open Systems Interconnection (OSI) layer protocols), intranets, enterprise networks, virtual private networks, wide area networks, local networks, private networks using communication protocols proprietary to one or more companies, and various combinations of the foregoing. Such communication may be facilitated by any device capable of transmitting data to and from other computing devices, such as modems and wireless interfaces.

The computing devices may be configured to implement the logic synthesis optimization techniques discussed herein. In some examples, client computing device 804 may be an engineering workstation used by a developer to perform circuit design and/or other processes for IC design and fabrication. Client computing device 806 may also be used by a developer, for instance to prepare system requirements for the IC or manage the manufacturing process with the fabrication facility 812. Servers 802 may also be used via the client devices 804, 806 to perform EDM processes, such as EDM flow 100 of FIG. 1, including tasks/operations of one or more of front-end design flow 102, logic synthesis 105, and/or physical design flow 110, including the Eulerpath-based transistor placement optimization process(es) discussed herein. For example, one or more servers 802 (or individual virtual machines or containers running on the server(s) 802) may, based on commands/instructions from a client device 804 and/or 806, operate Eulerpath-based transistor placement process 700 of FIG. 7 and/or the Eulerpath-based transistor placement algorithm discussed with respect to FIGS. 3 to 6 to optimize chip area and routing resources during custom cell design, or during placement 116 and/or routing 124 of the EDA flow 100. The optimized netlist and/or physical design may then be used as a basis for fabricating ICs at the fab 812 based on, for example IC layout 160.

Storage system 808 can be of any type of computerized storage capable of storing information accessible by the server computing devices 802, 804 and/or 806, such as a hard-drive, memory card, ROM, RAM, DVD, CD-ROM, flash drive and/or tape drive. In addition, storage system 808 may include a distributed storage system where data is stored on a plurality of different storage devices which may be physically located at the same or different geographic locations. Storage system 808 may be connected to the computing devices via the network 810 as shown in FIGS. 8A-8B, and/or may be directly connected to or incorporated into any of the computing devices. Storage system 808 may store various types of information. For instance, the storage system 808 may store one or more optimization algorithms, ground-truth datasets, trained ML models, AIGs, netlists, IC designs and/or layouts, and/or other IC-related data. Alternatively or additionally, storage system 808 may store the any final circuitry designs that may be provided for circuit fabrication by facility 812.

### 5. Further Remarks

For the purposes of the present disclosure, the singular forms “a,” “an” and “the” are intended to include plural forms as well, unless the context clearly indicates otherwise. The terms “comprises” and/or “comprising,” when used herein, specify the presence of stated features, integers, steps, operations, elements, and/or components, but do not preclude the presence or addition of one or more other features, integers, steps, operations, elements, components, and/or groups and/or combinations thereof. Additionally, the phrase “A and/or B” means (A), (B), or (A and B), and the phrase “A, B, and/or C” means (A), (B), (C), (A and B), (A and C), (B and C), or (A, B and C). The phrase “X(s)” means one or more X, a set of X, or a plurality of X. As used herein, the term “each” refers to each member of a set or each member of a subset of a set. The phrases “in an embodiment,” “In some embodiments,” “in one implementation,” “In some implementations,” “in some examples”, and other similar phrases used herein may refer to one or more of the same or different embodiments, implementations, and/or examples. Furthermore, the terms “comprising,” “including,” “having,” and the like, as used with respect to the present.

Reference to “one or more processors” herein includes situations where a set of processors may be configured to perform one or more operations. Any combination of such a set of processors may perform individual operations or a group of operations, in series and/or in parallel. This may include two or more CPUs, GPUs, TPUs, NPUs, QPUs, ASICs, FPGAs, DSPs, PLDs (or other hardware-based processing elements), or any combination thereof. It may also include situations where the processors have multiple processing cores. Therefore, reference to “one or more” such devices do not require that all processing elements (or cores) in the set must each perform all of the operations. Rather, unless expressly stated, any one of the one or more processing elements (or cores) may perform different operations when a set of operations is indicated, and different processing elements (or cores) may perform specific operations, either sequentially or in parallel.

References to “optimization” herein includes a situation, act, process, or methodology of making something (e.g., a design, system, decision, etc.) as efficient, functional, or effective as possible. Additionally, references to “optimal” herein may include a desirable or satisfactory end, outcome, or output. Moreover, references to an “optimum” herein may refer to the amount or degree of something that is favorable to some end and/or an extrema (maximum or minimum) point of the objective function.

Unless otherwise specifically noted, articles depicted in the drawings are not necessarily drawn to scale. In the appended drawings, which are not necessarily drawn to scale, like numerals may describe similar components in different views. Like numerals having different letter suffixes may represent different instances of similar components.

Although the technology herein has been described with reference to particular embodiments and configurations, it is to be understood that these are merely illustrative of the principles and applications of the present technology. It is therefore to be understood that numerous modifications may be made to the illustrative embodiments and that other arrangements may be devised without departing from the spirit and scope of the present technology as defined by the appended claims. By way of example only, components that are illustrated as being arranged in series may have a complementary configuration in parallel; similarly, components that are illustrated as being arranged in parallel may have a complementary configuration in series.

1. A computer-implemented method of Eulerpath transistor placement, the method comprising:
converting, by at least one processor, a netlist into a graph data structure, wherein each node in the graph data structure represents either a transistor in the netlist or a net in the netlist;
identifying, by the at least one processor, a set of Eulerpaths in the graph data structure;
aligning, by the at least one processor, a subset of the identified set of Eulerpaths; and
placing, by the at least one processor, the aligned Eulerpaths on a chip canvas.

2. The method of claim 1, wherein edges in the graph data structure represent ohmic connections between transistors or nets.

3. The method of claim 1, wherein each node representing a net includes a net identifier and each node representing a transistor includes a gate net identifier and orientation information.

4. The method of claim 1, wherein identifying the set of Eulerpaths comprises:
performing, by the at least one processor, a graph search on the graph data structure.

5. The method of claim 4, wherein performing the graph search comprises:
navigating, by the at least one processor, the graph data structure starting from an initial net node, and iteratively traversing a transistor node and another net node until the initial net node is reached.

6. The method of claim 4, wherein identifying the set of Eulerpaths comprises:
identifying, by the at least one processor, a set of p-channel metal-oxide-semiconductor (PMOS) Eulerpaths by performing the graph search on subgraphs comprising PMOS transistors; and identifying, by the at least one processor, a set of n-channel metal-oxide-semiconductor (NMOS) Eulerpaths by performing the graph search on subgraphs comprising NMOS transistors.

7. The method of claim 1, wherein aligning the subset of the identified set of Eulerpaths comprises:
identifying, by the at least one processor, gate-aligned Eulerpaths among the identified set of Eulerpaths; or
identifying, by the at least one processor, source/drain-aligned Eulerpaths among the identified set of Eulerpaths.

8. The method of claim 1, wherein aligning the subset of the identified set of Eulerpaths comprises:
determining, by the at least one processor, a score for each identified Eulerpath based on at least one of an amount of diffusion sharing, a number of gate-alignments, a number of source/drain-alignments, or a number of parallel tracks.

9. The method of claim 8, further comprising:
maintaining, by the at least one processor, a subset of Eulerpaths in the set of Eulerpaths having higher scores than other Eulerpaths in the set of Eulerpaths.

10. The method of claim 1, wherein placing the aligned Eulerpaths on the chip canvas comprises:
placing, by the at least one processor, a Eulerpath or a reversed Eulerpath from the set of Eulerpaths at a current position on the chip canvas;
advancing, by the at least one processor, the current position by a length of the placed Eulerpath;
advancing, by the at least one processor, the current position to a next row in the chip canvas when the current position extends beyond a final column of the chip canvas;
placing, by the at least one processor, a next Eulerpath or a next reversed Eulerpath from the set of Eulerpaths at the current position;
when all of the Eulerpaths in the set of Eulerpaths have been placed, evaluating, by the at least one processor, a wire length of the placed Eulerpaths; and
annealing, by the at least one processor, the placement of the Eulerpaths when the evaluated wire length is better than a criterion.

11. A computing system, comprising:
at least one memory device configured to store instructions for performing Eulerpath transistor placement during electronic design automation; and
at least one processor connected to the at least one memory device, wherein the at least one processor is configured to execute the instructions to:
convert a netlist into a graph data structure, wherein each node in the graph data structure represents either a transistor in the netlist or a net in the netlist;
identify a set of Eulerpaths in the graph data structure;
align a subset of the identified set of Eulerpaths; and
place the aligned Eulerpaths on a chip canvas.

12. The system of claim 11, wherein edges in the graph data structure represent ohmic connections between transistors or nets.

13. The system of claim 11, wherein each node representing a net includes a net identifier and each node representing a transistor includes a gate net identifier and orientation information.

14. The system of claim 11, wherein identifying the set of Eulerpaths comprises:
perform a graph search on the graph data structure.

15. The system of claim 14, wherein performing the graph search comprises:
navigate the graph data structure starting from an initial net node, and iteratively traversing a transistor node and another net node until the initial net node is reached.

16. The system of claim 14, wherein identifying the set of Eulerpaths comprises:
identify a set of p-channel metal-oxide-semiconductor (PMOS) Eulerpaths by performing the graph search on subgraphs comprising PMOS transistors; and
identify a set of n-channel metal-oxide-semiconductor (NMOS) Eulerpaths by performing the graph search on subgraphs comprising NMOS transistors.

17. The system of claim 11, wherein aligning the subset of the identified set of Eulerpaths comprises:
identify gate-aligned Eulerpaths among the identified set of Eulerpaths; or
identify source/drain-aligned Eulerpaths among the identified set of Eulerpaths.

18. The system of claim 11, wherein aligning the subset of the identified set of Eulerpaths comprises:
determine a score for each identified Eulerpath based on at least one of an amount of diffusion sharing, a number of gate-alignments, a number of source/drain-alignments, or a number of parallel tracks.

19. The system of claim 18, wherein the at least one processor is configured to execute the instructions to:
maintain a subset of Eulerpaths in the set of Eulerpaths having higher scores than other Eulerpaths in the set of Eulerpaths.

20. The system of claim 11, wherein placing the aligned Eulerpaths on the chip canvas comprises:
place a Eulerpath or a reversed Eulerpath from the set of Eulerpaths at a current position on the chip canvas;
advance the current position by a length of the placed Eulerpath;
advance the current position to a next row in the chip canvas when the current position extends beyond a final column of the chip canvas;
place a next Eulerpath or a next reversed Eulerpath from the set of Eulerpaths at the current position;
when all of the Eulerpaths in the set of Eulerpaths have been placed, evaluate a wire length of the placed Eulerpaths; and
anneal the placement of the Eulerpaths when the evaluated wire length is better than a criterion.
